(19) United States
(12) Patent Application Publication
(10) Pub. No.: US 2023/0096932 A1
(43) Pub. Date: Mar. 30, 2023

(54) SURFACE EMITTING LASER

(71) Applicant: SONY SEMICONDUCTOR SOLUTIONS CORPORATION, KANAGAWA (JP)

(72) Inventors: KOTA TOKUDA, KANAGAWA (JP); OSAMU MAEDA, KUMAMOTO (JP); YOSHIHIKO TAKAHASHI, KUMAMOTO (JP); KAZUHIKO TAKAHASHI, KUMAMOTO (JP)

(21) Appl. No.: 17/802,959

(22) PCT Filed: Feb. 17, 2021
(86) PCT No.: PCT/JP2021/005974

§ 371 Date: Aug. 28, 2022

(30) Foreign Application Priority Data
Mar. 5, 2020 (JP) 2020-037915

(51) Int. Cl. H01S 5/183

(52) U.S. Cl. CPC H01S 5/18361; H01S 5/18305; H01S 5/18347

(57) ABSTRACT

A surface emitting laser according to one embodiment of the present disclosure includes a mesa part including, in order, a first conductivity-type DBR layer, an active layer, a second conductivity-type DBR layer, and a second conductivity-type contact layer. The surface emitting laser further includes: a first conductivity-type contact layer provided in a region on the first conductivity-type DBR layer side in a positional relationship with respect to the mesa part; a first conductivity-type semiconductor layer that is disposed at a position opposed to the mesa part with the first conductivity-type contact layer interposed therebetween, and is in contact with the first conductivity-type contact layer, the first conductivity-type semiconductor layer having a lower impurity concentration than the first conductivity-type contact layer; a first electrode layer in contact with the first conductivity-type contact layer; and a second electrode layer in contact with the second conductivity-type contact layer.

### TECHNICAL FIELD

The present disclosure relates to a surface emitting laser.

### BACKGROUND ART

A surface emitting laser that emits laser light from a top face of a mesa part has been known (e.g., PTL 1).

### CITATION LIST

### Patent Literature

PTL 1: Japanese Unexamined Patent Application Publication No. 2008-283028

### SUMMARY OF THE INVENTION

Incidentally, in a case of emitting laser light from a back surface, it may be possible to use a semi-insulating substrate as a substrate, provide a contact layer between the substrate and a DBR (distributed Bragg reflector) layer, and provide an electrode on the contact layer. Using the semi-insulating substrate as the substrate makes it possible to suppress light absorption. The contact layer serves for both a reduction in contact resistance between the electrode and the DBR layer and hole transportation from the electrode into a mesa part. This causes light absorption due to an impurity in the contact layer. It is possible to suppress light absorption by making the contact layer between the substrate and the DBR layer thinner, but in such a case, a resistance value of the contact layer increases, and a drive voltage also increases. Accordingly, it is desirable to provide a surface emitting laser that makes it possible to achieve both high optical output and low drive voltage.

A surface emitting laser according to one embodiment of the present disclosure includes a mesa part including, in order, a first conductivity-type DBR layer, an active layer, a second conductivity-type DBR layer, and a second conductivity-type contact layer. The surface emitting laser further includes: a first conductivity-type contact layer provided in a region on the first conductivity-type DBR layer side in a positional relationship with respect to the mesa part; a first conductivity-type semiconductor layer that is disposed at a position opposed to the mesa part with the first conductivity-type contact layer interposed therebetween, and is in contact with the first conductivity-type contact layer, the first conductivity-type semiconductor layer having a lower impurity concentration than the first conductivity-type contact layer; a first electrode layer in contact with the first conductivity-type contact layer; and a second electrode layer in contact with the second conductivity-type contact layer.

In the surface emitting laser according to one embodiment of the present disclosure, the first conductivity-type contact layer and the first conductivity-type semiconductor layer are formed in the region on the first conductivity-type DBR layer side in the positional relationship with respect to the mesa part. The first conductivity-type semiconductor layer is in contact with the first conductivity-type contact layer and has the lower impurity concentration than the first conductivity-type contact layer. Thus, by making the first conductivity-type contact layer with the relatively high impurity concentration relatively thin and making the first conductivity-type semiconductor layer with the relatively low impurity concentration relatively thick, for example, it is possible to suppress a resistance value between the first electrode layer and the first conductivity-type DBR layer to a low level, while suppressing light absorption by the first conductivity-type contact layer.

### BRIEF DESCRIPTION OF THE DRAWINGS

FIG. 1 is a diagram illustrating a cross-sectional configuration example of a surface emitting laser according to an embodiment of the present disclosure.

FIG. 2 is a diagram illustrating an example of a manufacturing step of the surface emitting laser of FIG. 1.

FIG. 3 is a diagram illustrating an example of a manufacturing step following FIG. 2.

FIG. 4 is a diagram illustrating an example of a manufacturing step following FIG. 3.

FIG. 5 is a diagram illustrating an example of a manufacturing step following FIG. 4.

FIG. 6 is a diagram illustrating an example of a manufacturing step following FIG. 5.

FIG. 7 is a diagram illustrating a modification example of a cross-sectional configuration of the surface emitting laser of FIG. 1.

FIG. 8 is a diagram illustrating a modification example of a cross-sectional configuration of the surface emitting laser of FIG. 1.

### MODES FOR CARRYING OUT THE INVENTION

Hereinafter, embodiments of the present disclosure are described in detail with reference to the drawings. The following description is one specific example of the present disclosure, and the present disclosure is not limited to the following embodiment. In addition, the present disclosure is not limited to arrangement, dimensions, dimensional ratios, and the like of the constituent elements illustrated in the respective drawings.

### Embodiment

### [Configuration]

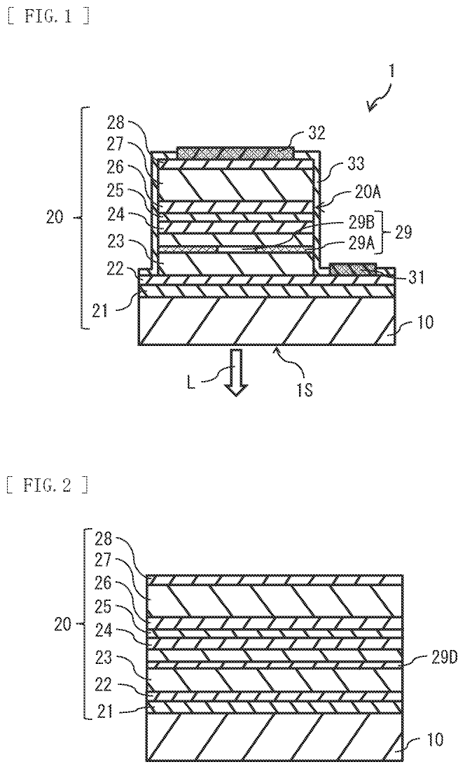

A surface emitting laser 1 according to an embodiment of the present disclosure will be described. FIG. 1 illustrates a cross-sectional configuration example of the surface emitting laser 1.

The surface emitting laser 1 includes a vertical resonator on a substrate 10. The vertical resonator is configured to oscillate at an oscillation wavelength λ₀ by two DBR (distributed Bragg reflector) layers (a p-type DBR layer 23 and an n-type DBR layer 27) that are opposed to each other in a normal direction of the substrate 10. The p-type DBR layer 23 corresponds to one specific example of a “first conductivity-type DBR layer” of the present disclosure. The n-type DBR layer 27 corresponds to one specific example of a “second conductivity-type DBR layer” of the present disclosure. The p-type DBR layer 23 is formed at a position closer to the substrate 10 than the n-type DBR layer 27 is. The n-type DBR layer 27 is formed at a position farther from the substrate 10 than the p-type DBR layer 23 is. The surface emitting laser 1 is configured to allow laser light L to be emitted from the p-type DBR layer 23 side. Therefore, the surface emitting laser 1 is a back-surface emitting laser having a light output surface 1S for the laser light L on a back surface.

The surface emitting laser 1 includes, on the substrate 10, an epitaxial stacked structure 20 formed by an epitaxial crystal growth method using the substrate 10 as a crystal growth substrate. The epitaxial stacked structure 20 includes, for example, a p-type current diffusion layer 21, a p-type contact layer 22, the p-type DBR layer 23, a spacer layer 24, an active layer 25, a spacer layer 26, the n-type DBR layer 27, and an n-type contact layer 28 in this order from the substrate 10 side. The p-type contact layer 22 corresponds to one specific example of a “first conductivity-type contact layer” of the present disclosure. The p-type current diffusion layer 21 corresponds to one specific example of a “first conductivity-type semiconductor layer” of the present disclosure.

In the epitaxial stacked structure 20, the p-type DBR layer 23, the spacer layer 24, the active layer 25, the spacer layer 26, the n-type DBR layer 27, and the n-type contact layer 28 configure a columnar mesa part 20A extending in the normal direction of the substrate 10. The p-type current diffusion layer 21 and the p-type contact layer 22 are provided in a region on the p-type DBR layer 23 side in a positional relationship with respect to the mesa part 20A. The substrate 10 is disposed at a position opposed to the mesa part 20A with the p-type current diffusion layer 21 and the p-type contact layer 22 interposed therebetween.

The surface emitting laser 1 includes an electrode layer 32 in contact with the top of the mesa part 20A (i.e., the n-type contact layer 28), and includes an electrode layer 31 in contact with the p-type contact layer 22 spreading at a foot of the mesa part 20A. The n-type contact layer 28 is a layer for causing the n-type DBR layer 27 and the electrode layer 32 to be in ohmic contact with each other. The p-type contact layer 22 is a layer for causing the p-type DBR layer 23 and the electrode layer 31 to be in ohmic contact with each other. The electrode layer 32 is formed at least at a position opposed to a light-emitting region of the active layer 25. The electrode layer 32 corresponds to one specific example of a “second electrode layer” of the present disclosure. The electrode layer 31 corresponds to one specific example of a “first electrode layer” of the present disclosure.

The surface emitting laser 1 includes, for example, an arsenide semiconductor. The arsenide semiconductor refers to a compound semiconductor including an arsenic (As) element and including at least one or more elements out of aluminum (Al), gallium (Ga), and indium (In). The substrate 10 is, for example, a semi-insulating semiconductor substrate. Examples of the semi-insulating semiconductor substrate that may be used for the substrate 10 include a GaAs substrate. The substrate 10 may be a p-type semiconductor substrate. Examples of the p-type semiconductor substrate that may be used for the substrate 10 include a GaAs substrate having a p-type impurity concentration lower than a p-type impurity concentration of the p-type current diffusion layer 21. The substrate 10 has a resistivity that is, for example, larger than 1.0×10⁶ ohms and smaller than 1.0×10¹² ohms.

The p-type current diffusion layer 21 is in contact with the p-type contact layer 22 and electrically coupled to the p-type contact layer 22. The p-type current diffusion layer 21 configures, together with the p-type contact layer 22, a path of current that flows between the electrode layer 31 and the p-type DBR layer 23. The p-type current diffusion layer 21 is disposed at a position opposed to the mesa part 20A with the p-type contact layer 22 interposed therebetween. The p-type current diffusion layer 21 includes, for example, p-type Alₓ₁Ga₁₋ₓ₁As (0≤x1<1). The p-type contact layer 22 includes, for example, p-type Alₓ₂Ga₁₋ₓ₂As (0≤x2<1). The p-type impurity concentration of the p-type current diffusion layer 21 is lower than a p-type impurity concentration of the p-type contact layer 22. If the p-type impurity concentration of the p-type contact layer 22 is 2.0×10¹⁹ cm⁻³, the p-type impurity concentration of the p-type current diffusion layer 21 is 2.0×10¹⁸ cm⁻³ (a concentration lower than that of the p-type contact layer 22 by an order of magnitude). The p-type impurity concentration in the p-type current diffusion layer 21 may be uniform in a thickness direction and a direction orthogonal to the thickness, or may have a concentration distribution in the thickness direction. The p-type current diffusion layer 21 has a thickness that is thicker than a thickness of the p-type contact layer 22. If the thickness of the p-type contact layer 22 is 1000 nm, the thickness of the p-type current diffusion layer 21 is 2000 nm (a thickness about twice as large as that of the p-type contact layer 22).

The p-type DBR layer 23 has a configuration in which a low refractive index layer (not illustrated) and a high refractive index layer (not illustrated) are alternately stacked. In the p-type DBR layer 23, the low refractive index layer includes p-type Alₓ₃Ga₁₋ₓ₃As (0<x3<1) having an optical thickness of λ₀×¼ (λ₀ is the oscillation wavelength), for example, and the high refractive index layer includes p-type Alₓ₄Ga₁₋ₓ₄ As (0≤x4<x3) having an optical thickness of λ₀×¼, for example. The spacer layer 24 includes, for example, p-type Alₓ₅Ga₁₋ₓ₅As (0≤x5<1). Examples of a p-type impurity in the p-type current diffusion layer 21, the p-type contact layer 22, the p-type DBR layer 23, and the spacer layer 24 include carbon (C).

The active layer 25 has, for example, a multi-quantum-well structure in which a well layer (not illustrated) that includes undoped Inₓ₆Ga₁₋ₓ₆As (0<x6<1) and a barrier layer (not illustrated) that includes undoped Inₓ₇Ga₁₋ₓ₇As (0<x7<x6) are alternately stacked. It is to be noted that a region, of the active layer 25, opposed to a current injection region 29B (to be described later) serves as the light-emitting region.

The spacer layer 26 includes, for example, n-type Alₓ₈Ga₁₋ₓ₈As (0≤x8<1). The n-type DBR layer 27 has a configuration in which a low refractive index layer (not illustrated) and a high refractive index layer (not illustrated) are alternately stacked. In the n-type DBR layer 27, the low refractive index layer includes, for example, n-type Alₓ₉Ga₁₋ₓ₉As (0<x9<1) having an optical thickness of λ₀×¼, and the high refractive index layer includes, for example, n-type Alₓ₁₀Ga₁₋ₓ₁₀As (0≤x10<x9) having an optical thickness of λ₀×¼. The n-type DBR layer 27 is configured to have a greater reflectance than the p-type DBR layer 23, with respect to the oscillation wavelength 4 of the vertical resonator in the mesa part 20A. The n-type DBR layer 27 is, for example, formed thicker than the p-type DBR layer 23. The n-type contact layer 28 includes, for example, n-type Alₓ₁₁Ga₁₋ₓ₁₁As (0≤x11<1). Examples of an n-type impurity in the spacer layer 26, the n-type DBR layer 27, and the n-type contact layer 28 include silicon (Si).

The epitaxial stacked structure 20 includes a current constriction layer 29 in the p-type DBR layer 23 or between the p-type DBR layer 23 and the spacer layer 24. The current constriction layer 29 has the current injection region 29B and a current constriction region 29A. The current constriction region 29A is formed in a surrounding region of the current injection region 29B. The current injection region 29B includes, for example, p-type Alₓ₁₂Ga₁₋ₓ₁₂As (0<x12≤1). The current constriction region 29A includes, for example, Al₂O₃ (aluminum oxide), and is obtained, for example, by oxidizing high concentration of Al included in an oxidized layer 29D (described later) from a side face. Accordingly, the current constriction layer 29 has the function of constricting a current.

The electrode layer 31 is in contact with a surface, of the p-type contact layer 22, on the mesa part 20A side. The electrode layer 31 includes a non-alloy, and is a stacked body in which, for example, Ti, Pt, and Au are stacked in order from the p-type contact layer 22 side. The electrode layer 32 includes an alloy, and is a stacked body in which, for example, AuGe, Ni, and Au are stacked in order from the n-type contact layer 28 side. An insulating layer 33 is formed around the mesa part 20A. The insulating layer 33 is a layer for protecting the mesa part 20A, and includes, for example, a stacked body in which SiO₂, Si, and SiO₂ are stacked in this order.

### [Manufacturing Method]

Next, a manufacturing method of the surface emitting laser 1 according to the present embodiment will be described. FIGS. 2 to 6 illustrate an example of a manufacturing procedure of the surface emitting laser 1.

In order to manufacture the surface emitting laser 1, compound semiconductors are collectively formed on the substrate 10 that includes GaAs, for example, by an epitaxial crystal growth method such as MOCVD (Metal Organic Chemical Vapor Deposition: Metal Organic Vapor Deposition) method. At this time, as raw materials of the compound semiconductors, for example, a methyl-based organometallic gas such as trimethylaluminum (TMAl), trimethylgallium (TMGa), or trimethylindium (TMIn) and an arsine (AsH₃) gas are used, and disilane (Si₂H₆), for example, is used as a raw material of a donor impurity. For example, carbon tetrabromide (CBr₄) is used as a raw material of an acceptor impurity.

First, the epitaxial stacked structure 20 including the p-type current diffusion layer 21, the p-type contact layer 22, the p-type DBR layer 23, the spacer layer 24, the active layer 25, the spacer layer 26, the n-type DBR layer 27, and the n-type contact layer 28 is formed on a surface of the substrate 10 by an epitaxial crystal growth method such as a MOCVD method (FIG. 2).

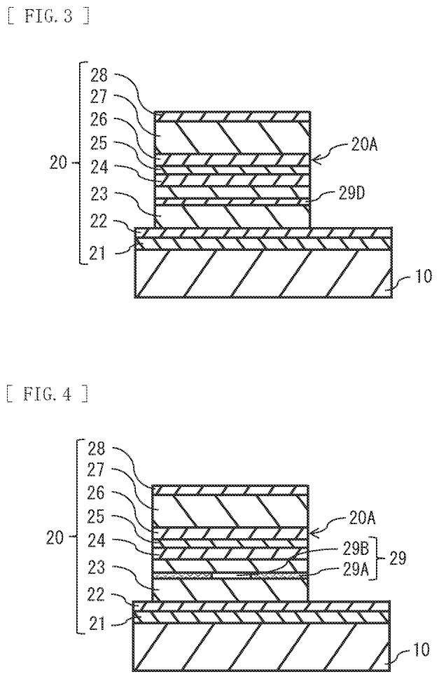

Next, for example, a circular resist layer (not illustrated) is formed, following which the epitaxial stacked structure 20 is selectively etched using the resist layer as a mask, and the epitaxial stacked structure 20 is etched to a depth reaching the p-type contact layer 22. At this time, it is preferable to use, for example, RIE (Reactive Ion Etching) by a Cl-based gas. In this way, the columnar mesa part 20A is formed, for example, as illustrated in FIG. 3. At this time, the p-type contact layer 22 is exposed at the foot of the mesa part 20A. In addition, the oxidized layer 29D is exposed on the side face of the mesa part 20A. Thereafter, the resist layer is removed.

Next, an oxidation treatment is performed in a water vapor atmosphere at a high temperature to selectively oxidize Al included in the oxidized layer 29D from the side face of the mesa part 20A. Alternatively, Al included in the oxidized layer 29D is selectively oxidized from the side face of the mesa part 20A by a wet oxidation method. Thus, an outer edge region of the oxidized layer 29D becomes an insulation layer (aluminum oxide) in the mesa part 20A, and the current constriction layer 29 is formed (FIG. 4).

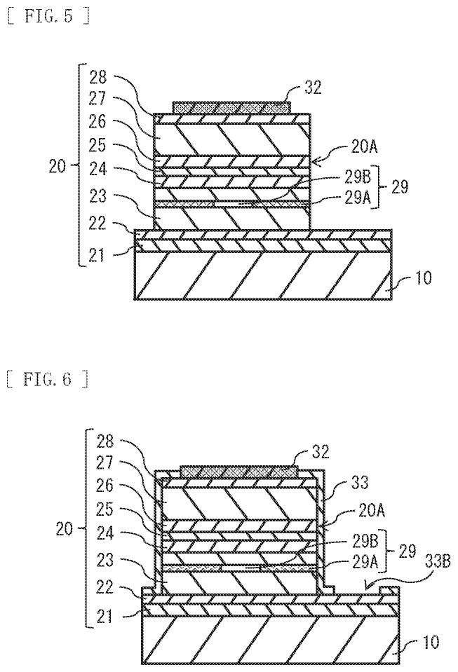

Next, the electrode layer 32 in contact with a top face of the mesa part 20A (e.g., the n-type contact layer 28) is formed, following which the insulating layer 33 covering the mesa part 20A is formed (FIGS. 5 and 6). At this time, an opening 33B is formed at a predetermined location of the foot of the mesa part 20A. Next, in the opening 33B, the electrode layer 31 in contact with the surface, of the p-type contact layer 22, on the mesa part 20A side is formed. In this way, the surface emitting laser 1 is manufactured.

### [Operation]

In the surface emitting laser 1 having such a configuration, if a predetermined voltage is applied between the electrode layer 31 electrically coupled to the p-type DBR layer 23 and the electrode layer 32 electrically coupled to the n-type DBR layer 27, a current constricted by the current constriction layer 29 is injected into the active layer 25, thereby causing light emission to occur as a result of recombination of electrons and holes. As a result, the vertical resonator in the mesa part 20A generates laser oscillation at the oscillation wavelength λ₀. Light leaking out of the p-type DBR layer 23 is then outputted from the light output surface 1S to the outside as the beam-shaped laser light L.

### [Effects]

Next, effects of the surface emitting laser 1 according to the present embodiment will be described.

In a case of emitting laser light from a back surface, it may be possible to use a semi-insulating substrate as a substrate, provide a contact layer between the substrate and a DBR layer, and provide an electrode on the contact layer. Using the semi-insulating substrate as the substrate makes it possible to suppress light absorption. The contact layer serves for both a reduction in contact resistance between the electrode and the DBR layer and hole transportation from the electrode into a mesa part. This causes light absorption due to an impurity in the contact layer. It is possible to suppress light absorption by making the contact layer between the substrate and the DBR layer thinner, but in such a case, a resistance value of the contact layer increases, and a drive voltage also increases.

In contrast, in the present embodiment, the p-type contact layer 22, and the p-type current diffusion layer 21 in contact with the p-type contact layer 22 and having the lower impurity concentration than the p-type contact layer 22 are formed in the region on the p-type DBR layer 23 side in the positional relationship with respect to the mesa part 20A. Thus, by making the p-type contact layer 22 with the relatively high impurity concentration relatively thin and making the p-type current diffusion layer 21 with the relatively low impurity concentration relatively thick, it is possible to suppress the resistance value between the electrode layer 31 and the p-type DBR layer 23 to a low level, while suppressing light absorption by the p-type contact layer 22. This makes it possible to achieve both high optical output and low drive voltage.

In the present embodiment, the substrate 10 is provided at the position opposed to the mesa part 20A with the p-type contact layer 22 and the p-type current diffusion layer 21 interposed therebetween, and the electrode layer 31 is provided at the position in contact with the surface, of the p-type contact layer 22, on the mesa part 20A side. This makes it possible to support the mesa part 20A and the electrode layer 31 by the substrate 10, while suppressing light absorption at the substrate 10. In addition, the electrode layers 31 and 32 are provided in a region on the opposite side to the light output surface 1S in a positional relationship with respect to the substrate 10. Thus, by bonding together the surface emitting laser 1 and a circuit board including a circuit that drives the surface emitting laser 1, for example, it is possible to provide electric contact between the surface emitting laser 1 and the circuit that drives the surface emitting laser 1.

In the present embodiment, the p-type current diffusion layer 21, the p-type contact layer 22, the p-type DBR layer 23, the spacer layer 24, the active layer 25, the spacer layer 26, the n-type DBR layer 27, and the n-type contact layer 28 are formed by the epitaxial crystal growth method using the substrate 10 as the crystal growth substrate. This makes it possible to precisely control the thickness and the impurity concentration of the p-type current diffusion layer 21 and the p-type contact layer 22. By making the p-type contact layer 22 with the relatively high impurity concentration relatively thin and making the p-type current diffusion layer 21 with the relatively low impurity concentration relatively thick, for example, it is possible to suppress the resistance value between the electrode layer 31 and the p-type DBR layer 23 to a low level, while suppressing light absorption by the p-type contact layer 22. This makes it possible to achieve both high optical output and low drive voltage.

In the present embodiment, the n-type DBR layer 27 is configured to have a greater reflectance than the p-type DBR layer 23, with respect to the oscillation wavelength λ₀ of the vertical resonator in the mesa part 20A. This makes it possible to cause most of the laser light L amplified by the vertical resonator in the mesa part 20A to be emitted from the p-type DBR layer 23 side.

In the present embodiment, the semiconductor layer (the p-type current diffusion layer 21, the p-type contact layer 22, the p-type DBR layer 23, and the spacer layer 24) provided on a light output side in the epitaxial stacked structure 20 includes a p-type semiconductor. A p-type impurity is a material that is more likely to cause light absorption loss for the laser light L than an n-type impurity. Therefore, to reduce light absorption loss, it is necessary to reduce the concentration of the p-type impurity. Because the laser light L passes through a part of the current path between the electrode layer 31 and the p-type DBR layer 23, to reduce light absorption loss, it is necessary that a layer with high p-type impurity concentration be as thin as possible in the current path between the electrode layer 31 and the p-type DBR layer 23. In the present embodiment, the p-type contact layer 22 serving as the layer with high p-type impurity concentration is made thin, and the p-type current diffusion layer 21 is made thick. This suppresses the resistance value between the electrode layer 31 and the p-type DBR layer 23 to a low level, while suppressing light absorption by the p-type contact layer 22. This makes it possible to achieve both high optical output and low drive voltage, even in a case where the semiconductor layer provided on the light output side in the epitaxial stacked structure 20 includes a p-type semiconductor.

### MODIFICATION EXAMPLES

### Modification Example A

In the embodiment described above, the epitaxial stacked structure 20 may include an undoped layer 34 between the substrate 10 and the p-type current diffusion layer 21, for example, as illustrated in FIG. 7. The undoped layer 34 includes, for example, undoped Alₓ₁₃Ga₁₋ₓ₁₃As (0<x13≤1). Providing the undoped layer 34 makes it difficult for current to flow in a high defect density region present in the substrate 10, which makes it possible to more efficiently reduce contact resistance between the electrode layer 31 and the p-type DBR layer 23. This enables the p-type current diffusion layer 21 to serve for efficient injection of hole carriers into the mesa part 20A. This makes it possible to achieve both high optical output and low drive voltage.

### Modification Example B

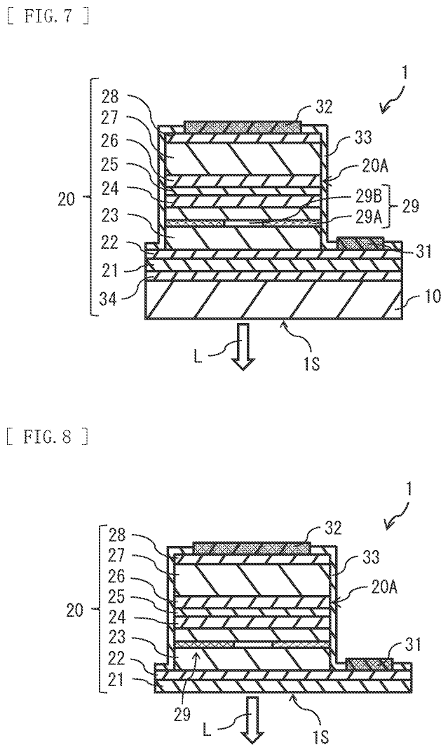

In the above embodiments and modification examples thereof, the substrate 10 may be omitted, for example, as illustrated in FIG. 8. For the substrate 10, a lift-off layer may be provided between the substrate 10 and the epitaxial stacked structure 20, and laser or the like may be applied to the lift-off layer, for example, which makes it possible to peel off the substrate 10. By peeling off the substrate 10 in this way, it is possible to prevent light absorption loss due to the substrate 10 and an increase in contact resistance. This makes it possible to achieve both high optical output and low drive voltage. It is to be noted that, in the present modification example, the electrode 31 may be in contact with the surface, of the p-type contact layer 22, on the mesa part 20A side, or may be in contact with a surface, of the p-type contact layer 22, on the opposite side to the mesa part 20A (a surface on the light output side).

### Modification Example C

In the above embodiments and modification examples thereof, the semiconductor layer provided on the light output side in the epitaxial stacked structure 20 includes a p-type semiconductor, and the semiconductor layer provided on the opposite side to the light output side in the epitaxial stacked structure 20 includes an n-type semiconductor. However, in the above embodiments and modification examples thereof, the semiconductor layer provided on the light output side in the epitaxial stacked structure 20 may include an n-type semiconductor, and the semiconductor layer provided on the opposite side to the light output side in the epitaxial stacked structure 20 may include a p-type semiconductor.

### Modification Example D

The above embodiments and modification examples thereof describe, as an example, a case where the surface emitting laser 1 includes the arsenide semiconductor. However, in the above embodiments and modification examples thereof, the surface emitting laser 1 may include, for example, a Group III-V semiconductor including nitrogen (N), boron (B), antimony (Sb), or phosphorus (P).

Although the present disclosure has been described above with reference to the embodiments and the modification examples thereof, the present disclosure is not limited to the above embodiments and the like, and various modifications can be made. It is to be noted that the effects described in this specification are only exemplified. The effects of the present disclosure are not limited to the effects described herein. The present disclosure may have effects other than the effects described herein.

For example, the present disclosure may also be configured as follows.

(1)

A surface emitting laser including:

a mesa part including, in order, a first conductivity-type DBR (distributed Bragg reflector) layer, an active layer, a second conductivity-type DBR layer, and a second conductivity-type contact layer;

a first conductivity-type contact layer provided in a region on the first conductivity-type DBR layer side in a positional relationship with respect to the mesa part;

a first conductivity-type semiconductor layer that is disposed at a position opposed to the mesa part with the first conductivity-type contact layer interposed therebetween, and is in contact with the first conductivity-type contact layer, the first conductivity-type semiconductor layer having a lower impurity concentration than the first conductivity-type contact layer;

a first electrode layer in contact with the first conductivity-type contact layer; and

a second electrode layer in contact with the second conductivity-type contact layer.

(2)

The surface emitting laser according to (1), further including a semi-insulating semiconductor substrate or a second conductivity-type semiconductor substrate at a position opposed to the mesa part with the first conductivity-type contact layer and the first conductivity-type semiconductor layer interposed therebetween, in which

the first electrode is in contact with a surface, of the first conductivity-type contact layer, on the mesa part side.

(3)

The surface emitting laser according to (2), in which the first conductivity-type semiconductor layer, the first conductivity-type contact layer, the first conductivity-type DBR layer, the active layer, the second conductivity-type DBR layer, and the second conductivity-type contact layer are formed by an epitaxial crystal growth method using the semi-insulating semiconductor substrate or the second conductivity-type semiconductor substrate as a crystal growth substrate.

(4)

The surface emitting laser according to (2) or (3), further including an undoped semiconductor layer between the semi-insulating semiconductor substrate or the second conductivity-type semiconductor substrate and the first conductivity-type semiconductor layer.

(5)

The surface emitting laser according to any one of (1) to (4), in which the first conductivity-type semiconductor layer is thicker than the first conductivity-type contact layer.

(6)

The surface emitting laser according to any one of (1) to (5), in which the second conductivity-type DBR layer is configured to have a greater reflectance than the first conductivity-type DBR layer, with respect to an oscillation wavelength of a vertical resonator in the mesa part.

(7)

The surface emitting laser according to any one of (1) to (6), in which

the first conductivity type includes a p type, and

the second conductivity type includes an n type.

In the surface emitting laser according to one embodiment of the present disclosure, the first conductivity-type contact layer electrically coupled to the first conductivity-type DBR layer, and the first conductivity-type semiconductor layer are formed on the first conductivity-type DBR layer side with respect to the mesa part. The first conductivity-type semiconductor layer is in contact with the first conductivity-type contact layer and has the lower impurity concentration than the first conductivity-type contact layer. Thus, by making the first conductivity-type contact layer with the relatively high impurity concentration relatively thin and making the first conductivity-type semiconductor layer with the relatively low impurity concentration relatively thick, for example, it is possible to suppress a resistance value between the first electrode layer and the first conductivity-type DBR layer to a low level, while suppressing light absorption by the first conductivity-type contact layer. This makes it possible to achieve both high optical output and low drive voltage.

The present application claims the benefit of Japanese Priority Patent Application JP2020-037915 filed with the Japan Patent Office on Mar. 5, 2020, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A surface emitting laser comprising:
a mesa part including, in order, a first conductivity-type DBR (distributed Bragg reflector) layer, an active layer, a second conductivity-type DBR layer, and a second conductivity-type contact layer;
a first conductivity-type contact layer provided in a region on the first conductivity-type DBR layer side in a positional relationship with respect to the mesa part;
a first conductivity-type semiconductor layer that is disposed at a position opposed to the mesa part with the first conductivity-type contact layer interposed therebetween, and is in contact with the first conductivity-type contact layer, the first conductivity-type semiconductor layer having a lower impurity concentration than the first conductivity-type contact layer;
a first electrode layer in contact with the first conductivity-type contact layer; and
a second electrode layer in contact with the second conductivity-type contact layer.

2. The surface emitting laser according to claim 1, further comprising a semi-insulating semiconductor substrate or a second conductivity-type semiconductor substrate at a position opposed to the mesa part with the first conductivity-type contact layer and the first conductivity-type semiconductor layer interposed therebetween, wherein
the first electrode is in contact with a surface, of the first conductivity-type contact layer, on the mesa part side.

3. The surface emitting laser according to claim 2, wherein the first conductivity-type semiconductor layer, the first conductivity-type contact layer, the first conductivity-type DBR layer, the active layer, the second conductivity-type DBR layer, and the second conductivity-type contact layer are formed by an epitaxial crystal growth method using the semi-insulating semiconductor substrate or the second conductivity-type semiconductor substrate as a crystal growth substrate.

4. The surface emitting laser according to claim 2, further comprising an undoped semiconductor layer between the semi-insulating semiconductor substrate or the second conductivity-type semiconductor substrate and the first conductivity-type semiconductor layer.

5. The surface emitting laser according to claim 1, wherein the first conductivity-type semiconductor layer is thicker than the first conductivity-type contact layer.

6. The surface emitting laser according to claim 1, wherein the second conductivity-type DBR layer is configured to have a greater reflectance than the first conductivity-type DBR layer, with respect to an oscillation wavelength of a vertical resonator in the mesa part.

7. The surface emitting laser according to claim 1, wherein
the first conductivity type comprises a p type, and
the second conductivity type comprises an n type.
